(19) United States
(12) Patent Application Publication
(10) Pub. No.: US 2025/0070078 A1
(43) Pub. Date: Feb. 27, 2025

(54) ELECTRONIC DEVICES AND METHODS OF MANUFACTURING ELECTRONIC DEVICES

(71) Applicant: Amkor Technology Singapore Holding Pte. Ltd.

(72) Inventors: Sang Hyun Jin, Incheon (KR); Wang Gu Lee, Seoul (KR); Hee Jun Jang, Chungcheonbuk-do (KR); Jin Suk Jeong, Incheon (KR)

(73) Assignee: Amkor Technology Singapore Holding Pte. Ltd., (omitted)

(21) Appl. No.: 18/454,694

(22) Filed: Aug. 23, 2023

(51) Int. Cl. H01L 23/00

(52) U.S. Cl. CPC H01L 24/80; H01L 24/03; H01L 24/05; H01L 24/08; H01L 2224/0345; H01L 2224/03452; H01L 2224/03462; H01L 2224/05082; H01L 2224/05166; H01L 2224/05184; H01L 2224/05571; H01L 2224/05647; H01L 2224/08145; H01L 2224/08225; H01L 2224/80006; H01L 2224/80009; H01L 2224/80379; H01L 2224/80896; H01L 2924/05042; H01L 2924/05432; H01L 2924/05442; H01L 2924/059

(57) ABSTRACT

In one example, a redistribution structure is provided and comprises a substrate interconnect. A portion of a first capping layer is removed to expose a side of the substrate interconnect. The side of the substrate interconnect is recessed by a dishing height from a side of the first capping layer. An electronic component is provided over the first capping layer. The electronic component comprises a second capping layer and a component interconnect. The second capping layer is bonded with the first capping layer. Heat is applied to bond the substrate interconnect to the component interconnect. Other examples and related devices and methods are also disclosed herein.

### TECHNICAL FIELD

The present disclosure relates, in general, to electronic devices, and more particularly, to electronic devices and methods for manufacturing electronic devices.

### BACKGROUND

Prior electronic packages and methods for forming electronic packages are inadequate, resulting in, for example, excess cost, decreased reliability, relatively low performance, or package sizes that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIG. 1 shows a cross-sectional view of an example electronic device.

FIGS. 2A to 2L show an example method for manufacturing an electronic device.

FIG. 3 shows a cross-sectional view of an example electronic device.

FIG. 3A shows an enlarged view of region A of the example electronic device of FIG. 3.

FIGS. 4A to 4F show an example method for manufacturing an electronic device.

FIG. 4CA shows an enlarged view of region A of the electronic device in FIG. 4C.

FIG. 4DA shows an enlarged view of region A of the electronic device in FIG. 4D.

FIG. 4EA shows an enlarged view of region A of the electronic device in FIG. 4E.

FIG. 4FA shows an enlarged view of region A of the electronic device in FIG. 4F.

FIG. 5 shows a cross-sectional view of an example electronic device.

FIGS. 6A to 6H show an example method for manufacturing an electronic device.

The following discussion provides various examples of electronic devices and methods of manufacturing electronic devices. Such examples are non-limiting, and the scope of the appended claims should not be limited to the particular examples disclosed. In the following discussion, the terms “example” and “e.g.” are non-limiting.

The figures illustrate the general manner of construction, and descriptions and details of well-known features and techniques may be omitted to avoid unnecessarily obscuring the present disclosure. In addition, elements in the drawing figures are not necessarily drawn to scale. For example, the dimensions of some of the elements in the figures may be exaggerated relative to other elements to help improve understanding of the examples discussed in the present disclosure. The same reference numerals in different figures denote the same elements.

The term “or” means any one or more of the items in the list joined by “or.” As an example, “x or y” means any element of the three-element set {(x), (y), (x, y)}. As another example, “x, y, or z” means any element of the seven-element set {(x), (y), (z), (x, y), (x, z), (y, z), (x, y, z)}.

The terms “comprises,” “comprising,” “includes,” and “including” are “open ended” terms and specify the presence of stated features, but do not preclude the presence or addition of one or more other features.

The terms “first,” “second,” etc. may be used herein to describe various elements; however, the described elements should not be limited by these terms. These terms are only used to distinguish one element from another. Thus, for example, a first element discussed in this disclosure could be termed a second element without departing from the teachings of the present disclosure.

Unless specified otherwise, the term “coupled” may be used to describe two elements directly contacting each other or describe two elements indirectly coupled by one or more other elements. For example, if element A is coupled to element B, then element A can be directly contacting element B or indirectly coupled to element B by an intervening element C. Similarly, the terms “over” or “on” may be used to describe two elements directly contacting each other or describe two elements indirectly coupled by one or more other elements. As used herein, the term “coupled” can refer to an electrical coupling or a mechanical coupling.

### DESCRIPTION

An example of an electronic device includes a first electronic component and a dielectric structure that defines a via extending from an upper side of the dielectric structure to an upper side of the first electronic component. A first interconnect is disposed in the via. An upper side of the first interconnect is substantially coplanar with the upper side of the dielectric structure. A seed layer is disposed between the first interconnect and the dielectric structure. An end of the seed layer is recessed from the upper side of the dielectric structure and the upper side of the first interconnect. A capping layer is disposed on the dielectric structure and extends to the end of the seed layer between the first interconnect and the dielectric structure.

An example method of making an electronic device includes providing a redistribution structure comprising a substrate interconnect. A portion of a first capping layer is removed to expose a side of the substrate interconnect. The side of the substrate interconnect is recessed by a dishing height from a side of the first capping layer. An electronic component is provided over the first capping layer. The electronic component comprises a second capping layer and a component interconnect. The second capping layer is bonded with the first capping layer. Heat is applied to bond the substrate interconnect to the component interconnect.

Another example method of making an electronic device includes providing a first electronic component. A dielectric structure is provided over the first electronic component. A sidewall of the dielectric structure defines a via extending from an upper side of the dielectric structure to the first electronic component. A seed layer is provided over the first electronic component, the upper side of the dielectric structure, and the sidewall of the dielectric structure. A first component interconnect is provided over the seed layer. The first component interconnect fills the via and covers the side of the dielectric structure. A portion of the first component interconnect is removed to leave an upper side of the first component interconnect recessed from the seed layer. A portion of the seed layer is removed to expose the upper side of the dielectric structure. An end of the seed layer is recessed from the dielectric structure and between the first component interconnect and the dielectric structure.

Other examples are included in the present disclosure. Such examples may be found in the figures, in the claims, or in the description of the present disclosure.

Various examples of devices and methods tend to improve direct copper-to-copper bonding between interconnects. Thin, inorganic capping layers can be deposited on the mating surfaces between electronic components or other substrates. The inorganic capping layers can bond together and subsequently cause adjacent interconnects to bond with application of heat. The interconnects are dished or recessed below the capping layers before bonding, and the dishing height can be controlled based on the thickness of the capping layer during formation. The precise dishing depths disclosed herein tend to improve bonding performance by reducing the likelihood of bonding failures caused by dishing depths that are too shallow or too deep.

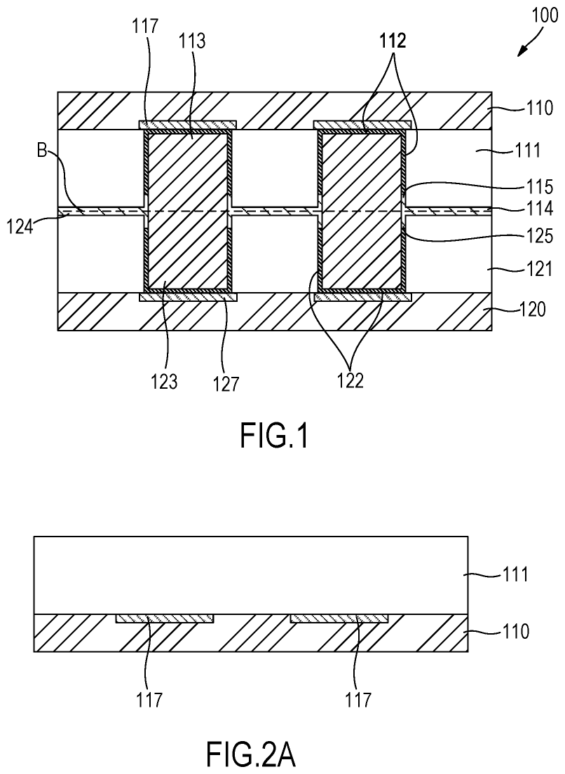

Referring now to FIG. 1, a cross-sectional view of an example electronic device 100 is shown. In the example of FIG. 1, electronic device 100 can comprise electronic component 110 and electronic component 120. Electronic component 110 can comprise dielectric structure 111, seed layer 112, interconnect 113, capping layer 114, recess 115, and bond pads 117. Electronic component 120 can comprise dielectric structure 121, seed layer 122, interconnect 123, capping layer 124, recess 125, and bond pads 127.

In some examples, interconnect 113 and interconnect 123 can be bonded directly together (e.g., in a direct copper-copper bond). A covalent bond can form between capping layer 114 and capping layer 124. The bond between interconnect 113 and interconnect 123 can be formed after the bond between capping layer 114 and capping layer 124. The bond between interconnect 113 and interconnect 123 can exhibit grain growth along the boundary or interface between the bonded interconnects. The height or thickness of capping layer 114 or capping layer 124 can be controlled during formation or deposition of the capping layer(s) to improve the reliability of bonding between interconnect 113 and interconnect 123. In the figures, dashed line B is representative of the bond or interface between interconnect 113 and interconnect 123 and between capping layer 114 and capping layer 124.

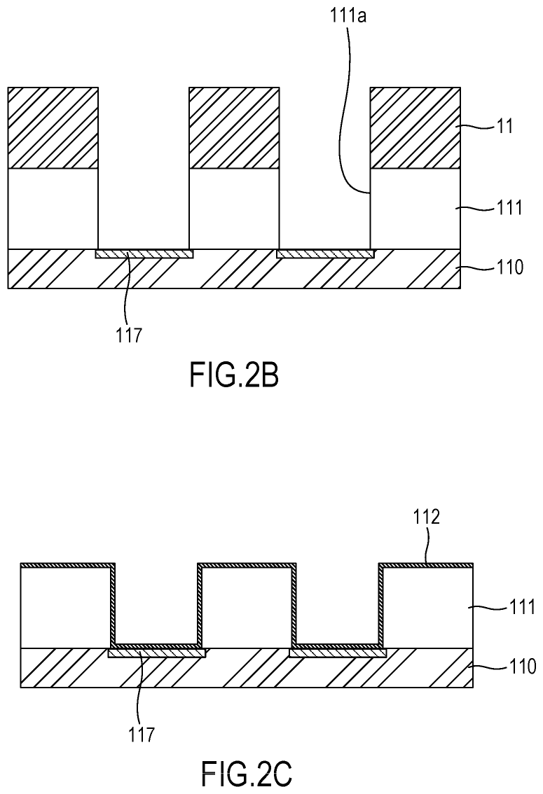

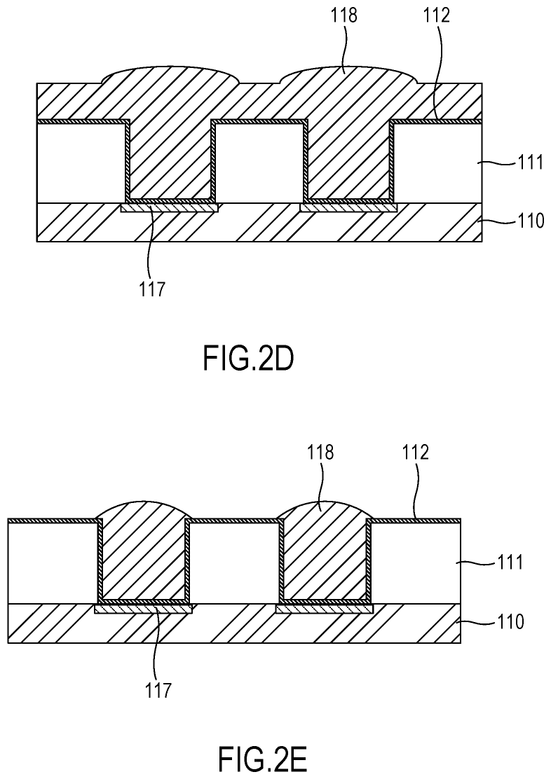

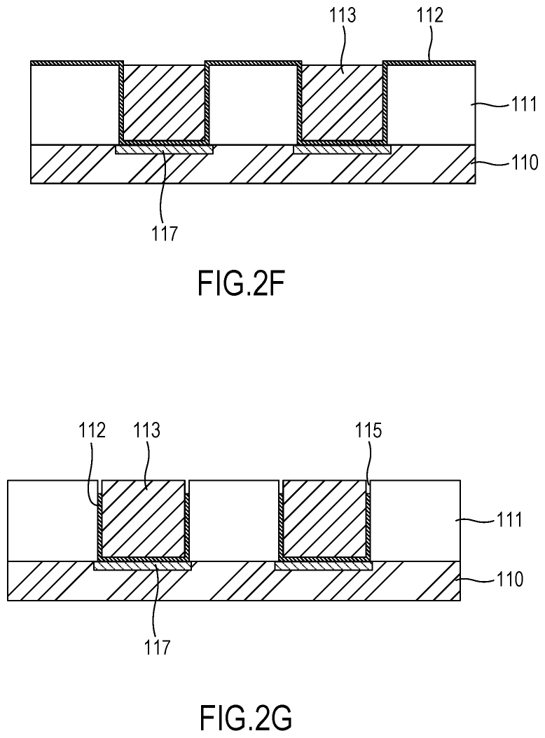

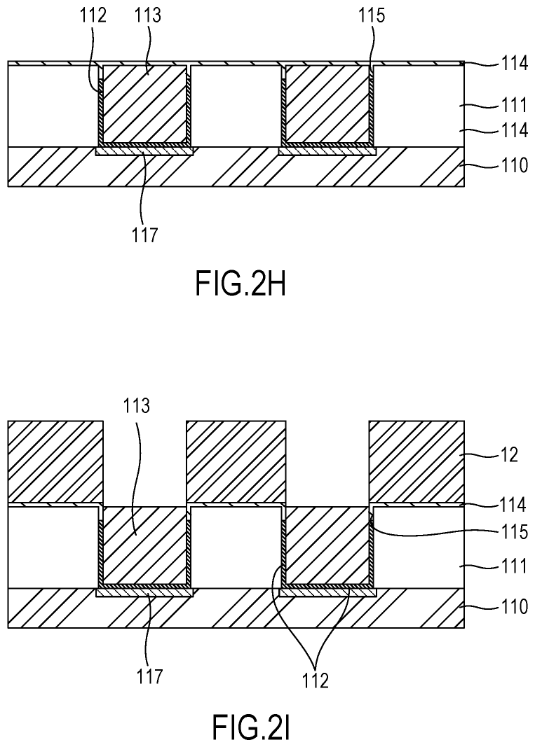

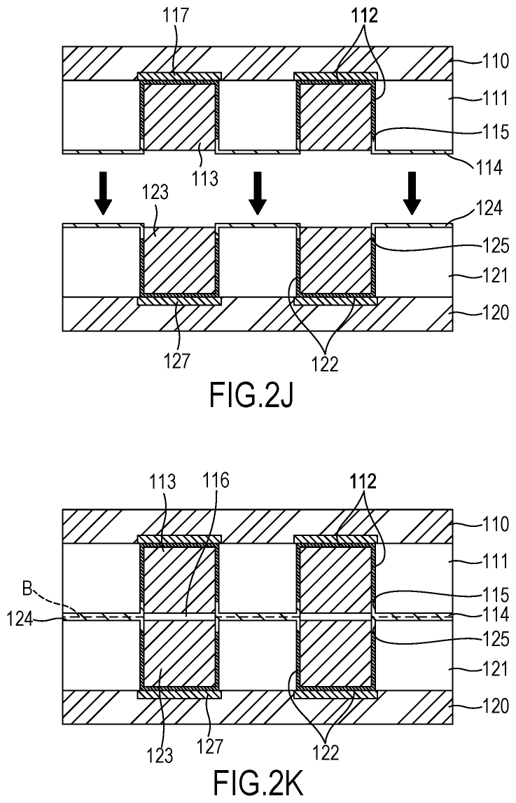

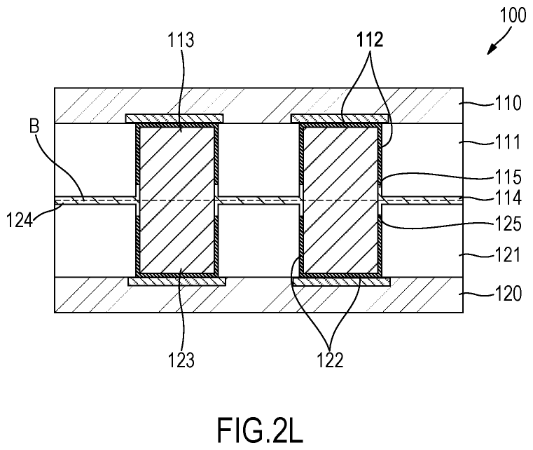

FIGS. 2A to 2L show cross-sectional views of an example method for manufacturing an example electronic device, such as electronic device 100 in FIG. 1. FIG. 2A shows electronic device 100 at an early stage of manufacture. In the example shown in FIG. 2A, dielectric structure 111 can be provided on electronic component 110. Electronic component 110 can comprise bond pads 117 on the front or active side of electronic component 110. Bond pads 117 can be input/output terminals of electronic component 110 and can be spaced apart from each other in rows or columns over the front side of electronic component 110. In some examples, electronic component 110 can comprise or be referred to as a die, a chip, a package, or a passive component. In some examples, the thickness of electronic component 110, as measured between the front side and the back side of electronic component 110, can range from approximately 50 micrometers (μm) to approximately 800 μm, and the area can range from approximately 0.5 millimeters (mm)×0.5 mm to approximately 70 mm×70 mm.

In some examples, dielectric structure 111 can be provided on the front side of electronic component 110. Dielectric structure 111 can be provided by physical vapor deposition (PVD), chemical vapor deposition (CVD), metal organic chemical vapor deposition (MOCVD), atomic layer deposition (ALD), low pressure chemical vapor deposition (LPCVD), plasma enhanced chemical vapor deposition (PECVD), spin coating, spray coating, dip coating, rod coating, printing, lamination, thermal oxidation, or any other suitable deposition process. In some examples, dielectric structure 111 can comprise one or more layers of organic dielectric material, such as, for example, photo imageable organic passivation material, PI (polyimide), BCB (benzocyclobutene), PBO (polybenzoxazole), phenolic resin, or ABF (Ajinomoto Buildup Film)). In some examples, dielectric structure 111 can comprise one or more layers of inorganic dielectric material such as, for example, SiO2, Si3N4, SiCN, SiON, or Al2O3. In some examples, the thickness of dielectric structure 111 can range from approximately 1 μm to approximately 20 μm.

FIG. 2B shows electronic device 100 at a later stage of manufacture. In the example of FIG. 2B, via 111a can be provided in dielectric structure 111. Via 111a can expose at least a portion of bond pad 117 on the front side of electronic component 110. In accordance with various examples, via 111a can be formed by providing mask 11 on the upper side of dielectric structure 111. Portions of dielectric structure 111 can be exposed by openings in mask 11. In some examples, mask 11 can be a photoresist. The exposed portions of dielectric structure 111 can be removed by, for example, etching, thereby forming vias 111a in dielectric structure 111. Via 111a can be defined by an interior sidewall of dielectric structure 111. Bond pads 117 of electronic component 110 can be exposed from dielectric structure 111 by vias 111a (i.e., dielectric structure 111 can expose bond pads 117 of electronic component 110). After forming vias 111a, mask 11 can be removed.

FIG. 2C shows electronic device 100 at a later stage of manufacture. In the example of FIG. 2C, seed layer 112 can be provided over or covering electronic component 110 and dielectric structure 111. Seed layer 112 can be provided with a substantially uniform thickness. Seed layer 112 can be disposed on bond pads 117 on the front side of electronic component 110, on the inner wall of via 111a (i.e., interior sidewall of dielectric structure 111), and the upper side of dielectric structure 111. Seed layer 112 can be coupled to the bond pads 117 of electronic component 110.

In some examples, seed layer 112 can be provided by sputtering, PVD, CVD, MOCVD, ALD, LPCVD, PECVD, or other suitable deposition process. Seed layer 112 can comprise Ti, TiW, or other suitable conductive seed material. In some examples, the thickness of seed layer 112 can range from approximately 0.05 μm to approximately 3 μm.

FIG. 2D shows electronic device 100 at a later stage of manufacture. In the example shown in FIG. 2D, interconnect material 118 can be provided to fill via 111a and can cover seed layer 112. In some examples, interconnect material 118 can be provided by electroplating using seed layer 112 as a seed for interconnect material 118. In some examples, an accelerant such as bis-(sodium sulfopropyl)-disulfide (SPS) can be used during formation to cause the interconnect material 118 to protrude above via 111a. Accelerant may be selectively applied over via 111a. The height of the portion of interconnect material 118 over via 111a, as measured from a plane corresponding with the upper surface of seed layer 112, can be greater than the height of the portion of interconnect material 118 over dielectric structure 111, as measured from the upper surface of seed layer 112. In some examples, portions of interconnect material 118 located on the upper side of dielectric structure 111 can be removed by chemical mechanical polishing (CMP). In some examples, portions of interconnect material 118 located on the upper side of dielectric structure 111 can be removed by reverse etching planarization in a later stage of manufacture.

FIG. 2E shows electronic device 100 at a later stage of manufacture. In the example shown in FIG. 2E, interconnect material 118 located on the upper side of dielectric structure 111 can be removed by isotropic etching. Removing the interconnect material 118 located on the upper side of dielectric structure 111 using isotropic etching tends to reduce or prevent residual interconnect material 118 from remaining on the upper side of seed layer 112 located on dielectric structure 111. In some examples, interconnect material 118 can protrude above seed layer 112 in an area corresponding to into via 111a (e.g., in an area within the footprint of via 111a).

FIG. 2F shows electronic device 100 at a later stage of manufacture. In the example of FIG. 2F, the portion of interconnect material 118 protruding above dielectric structure 111 (in FIG. 2E) can be removed, leaving interconnect 113. In some examples, the protruding portion of interconnect material 118 can be removed by CMP. Interconnect 113 can fill via 111a and can be recessed relative to seed layer 112. Interconnect 113 can be coupled to seed layer 112. Interconnect 113 can be coupled to the bond pads 117 of electronic component 110 through seed layer 112. In some examples, interconnect 113 can comprise copper. In some examples, interconnect 113 can be formed by plating. In some examples, interconnect 113 can be formed by over plating followed by the interconnect material removal steps described above.

In accordance with various examples, the height of interconnect 113, as measured from the front side of electronic component 110, can be similar to or the same as the height of dielectric structure 111, as measured from the front side of electronic component 110. In some examples, the height of interconnect 113 can range from approximately 1 μm to approximately 20 μm. As used herein with units of length, the term approximately can mean +/−5%, +/−10%, +/−15%, +/−20%, or +/−25%. In some examples, the upper side of seed layer 112 located on the upper side of dielectric structure 111 can be coplanar with the upper side of interconnect 113.

Seed layer 112 can be interposed between dielectric structure 111 and interconnect 113. Seed layer 112 can be interposed between interconnect 113 and bond pads 117 of electronic component 110.

FIG. 2G shows electronic device 100 at a later stage of manufacture. In the example shown in FIG. 2G, the portion of seed layer 112 covering the upper side of dielectric structure 111 can be removed. The upper side of dielectric structure 111 can be exposed after removal of seed layer 112. Seed layer 112 can be removed by, for example, wet etching. In some examples, an upper portion of seed layer 112 that is interposed between dielectric structure 111 and interconnect 113 can be removed. Recess 115 can be formed by the removal of the upper portion of seed layer 112 interposed between dielectric structure 111 and interconnect 113. Recess 115 can be defined between dielectric structure 111 and interconnect 113. Recess 115 can extend to an end of seed layer 112 along the sidewall of interconnect 113. The width of recess 115 can be similar to or the same as the thickness of seed layer 112. Recess 115 can comprise a trench surrounding an upper portion of interconnect 113. In some examples, the depth of recess 115, as measured from the upper side of interconnect 113 or the upper side of dielectric structure 111, can range from approximately 0.01 μm to approximately 1 μm.

FIG. 2H shows electronic device 100 at a later stage of manufacture. In the example shown in FIG. 2H, capping layer 114 can be provided over or covering dielectric structure 111, seed layer 112, and interconnect 113. Capping layer 114 can be in contact with the upper side of dielectric structure 111, the upper side of seed layer 112, and the upper side of interconnect 113. Capping layer 114 can fill recess 115 and can extend to the end of seed layer 112 between dielectric structure 111 and interconnect 113. Capping layer 114 can be interposed between the interior sidewall of dielectric structure 111 and interconnect 113.

In some examples, capping layer 114 can be provided by PVD, CVD, MOCVD, ALD, LPCVD, PECVD, spin coating, spray coating, dip coating, or rod coating. In some examples, capping layer 114 can be made of an inorganic material. For example, capping layer 114 can be at least one of SiO2, Si3N4, SiCN, SiON, or Al2O3. In some examples, the thickness of capping layer 114 can range from approximately 1 nanometer (nm) to approximately 100 nm. Capping layer 114 can also be referred to herein as a nano cap or nano-capping layer.

FIG. 2I shows electronic device 100 at a later stage of manufacture. In the example shown in FIG. 2I, the upper side of interconnect 113 can be exposed by removing a portion of capping layer 114. For example, mask 12 can be provided on the upper side of capping layer 114. Mask 12 can be patterned to expose portions of capping layer 114 located on interconnects 113. The exposed portions of capping layer 114 can be removed by etching. In some examples, mask 12 can comprise photoresist. Mask 12 can be removed after capping layer 114 is pattered (e.g., after portions of capping layer 114 are selectively removed to expose the top side of interconnects 113).

In some examples, electronic component 110 can comprise bond pads 117, dielectric structure 111, seed layer 112, interconnect 113, capping layer 114, and recess 115. The total height of capping layer 114 and dielectric structure 111 can be greater than the total height of interconnect 113 and seed layer 112. The upper side of capping layer 114 can protrude above the upper side of interconnect 113. Interconnect 113 can be dished or recessed relative to capping layer 114.

The dishing height or dishing depth can be controlled based on the thickness of the capping layer 114. The thickness of capping layer 114 tends to be highly controllable or accurate, thereby leading to improved bonding performance. Increased accuracy in dishing depth can allows for better or more accurate compensation in the difference in the thermal expansion coefficient between dielectric structure 111 and interconnect 113. Capping layer 114 can fill recess 115 between dielectric structure 111 and interconnect 113. Capping layer 114 can have an L-shaped profile with a portion over the upper side of dielectric structure 111 and a portion extending into recess 115 between dielectric structure 111 and interconnect 113.

FIG. 2J shows electronic device 100 at a later stage of manufacture. In the example shown in FIG. 2J, electronic component 110 can be located over electronic component 120. Electronic component 120 can comprise bond pads 127, dielectric structure 121, seed layer 122, interconnects 123, capping layer 124, and recess 125. Electronic component 120 can have elements, features, materials, or manufacturing methods the same as or similar to those of electronic component 110 manufactured by the process shown in FIGS. 2A to 2I. capping layer 114 of electronic component 110 and capping layer 124 of electronic component 120 can be bonded together. Although shown as a singulated electronic components in the example of FIG. 2J, it is contemplated and understood that electronic component 110 or electronic component 120 can be part of a wafer, a reconstituted wafer, or a redistribution layer (RDL) substrate, and the techniques and structures described in FIGS. 2A to 2I can be used to provide a redistribution structure or other substrate suitable for bonding to electronic component 110.

FIG. 2K shows electronic device 100 at a later stage of manufacture. In the example shown in FIG. 2K, capping layer 114 of electronic component 110 and capping layer 124 of electronic component 120 can be bonded together. In some examples, electronic component 110 can be flipped by pick-and-place equipment, so capping layer 114 can be located on the upper side of capping layer 124 of electronic component 120. Through a hybrid bonding process, capping layer 114 of electronic component 110 can be bonded to capping layer 124 of electronic component 120. For example, capping layer 114 and capping layer 124 can be subjected to surface activation before being bonded to each other. Surface activation can enable bonding at a low temperature. For example, in the surface activation of capping layer 114 and capping layer 124, hydrogen (H) atoms are generated on the sides of capping layer 114 and capping layer 124 through plasma treatment, and during plasma treatment, oxygen (O) particles separated from water or air bind with the hydrogen (H) on the sides of capping layer 114 and capping layer 124 to introduce hydroxy (OH) groups to the sides of capping layers 114 and 124. Capping layer 114 and capping layer 124 having hydroxy (OH) groups introduced to the sides can be easily coupled at low temperatures. In some examples, capping layer 114 and capping layer 124 can be coupled to each other at a temperature ranging from approximately 25° C. to approximately 400° C.

In some examples, after capping layer 114 of electronic component 110 and capping layer 124 of electronic component 120 are placed in contact, interconnect 113 of electronic component 110 and interconnect 123 of electronic component 120 can be spaced apart from each other to define void 116. In some examples, the passivation bond between capping layer 114 and capping layer 124 can initially start as a Van der Waals bond that progresses to a covalent bond through time or temperature. With the bond secured, interconnect 113 and interconnect 123 can be urged towards each other until void 116 is closed and a direct bond is established between interconnect 113 and interconnect 123.

FIG. 2L shows electronic device 100 at a later stage of manufacture. In the example shown in FIG. 2L, interconnect 113 of electronic component 110 is coupled to interconnect 123 of electronic component 120. Interconnect 113 and interconnect 123 can be coupled to each other at a higher temperature than a temperature for coupling capping layer 114 and capping layer 124. For example, interconnect 113 of electronic component 110 and interconnect 123 of electronic component 120 can be coupled to each other by a hybrid bonding process. In some examples, interconnect 113 and interconnect 123 can be coupled to each other at a temperature ranging from approximately 150° C. to approximately 400° C. Due to a temperature increase, interconnect 113 of electronic component 110 and interconnect 123 of electronic component 120 can expand as much as thicknesses of capping layers 114 and 124, and thus can be in contact with and be coupled to each other. Thermal expansion coefficients of interconnect 113 and interconnect 123 can be greater than the thermal expansion coefficients of capping layer 114 and capping layer 124. The void 116 (FIG. 2K) created by capping layer 114 and capping layer 124 can compensate for thermal expansion of interconnect 113 and interconnect 123.

When being coupled together, interconnect 113 and interconnect 123 can expand to be in contact with one another. Void 116 compensates for the thermal expansion of interconnects 113 and 123 and prevents or reduces the chances of capping layer 114 and capping layer 124 from being separated from each other. In some examples, the direct bond between interconnect 113 and interconnect 123 can comprise or be referred as a fusion bond or a solderless bond. In some examples, the direct bond can comprise grain growth of the material of interconnects 113, 123 into each other. In some examples, a direct bond can be established by pressure from interconnect 113 and interconnect 123 expanding towards each other due to heat while secured by the bond between capping layers 114 and 124.

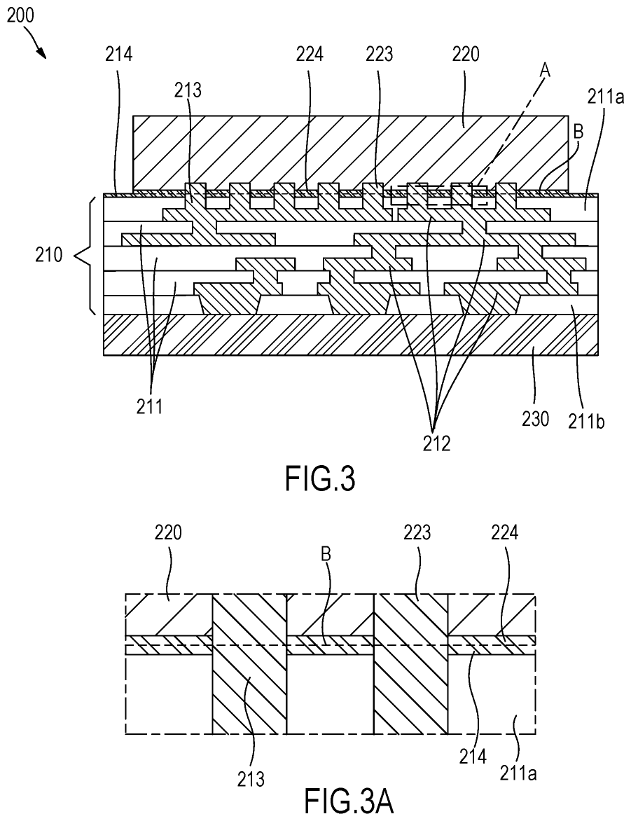

FIG. 3 shows a cross-sectional view of an example electronic device 200. FIG. 3A shows an enlarged view of region A of electronic device 200 of FIG. 3. In the example of FIGS. 3 and 3A, electronic device 200 can comprise redistribution structure 210 and electronic component 220. In some examples, electronic device 200 can comprise substrate 230.

In some examples, redistribution structure 210 can comprise dielectric structure 211, conductive structure 212, and substrate capping layer 214. Conductive structure 212 can comprise substrate interconnects 213. Dielectric structure 211 can comprise inner dielectric 211a and outer dielectric 211b. Electronic component 220 can comprise component interconnects 223 and component capping layer 224.

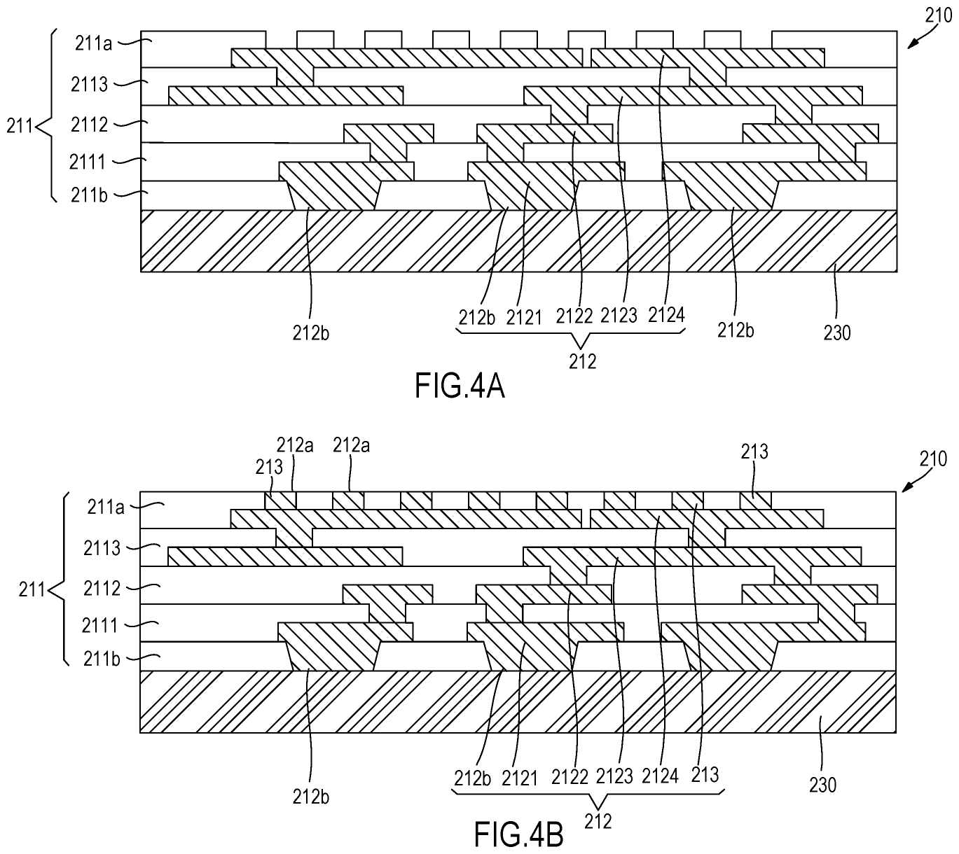

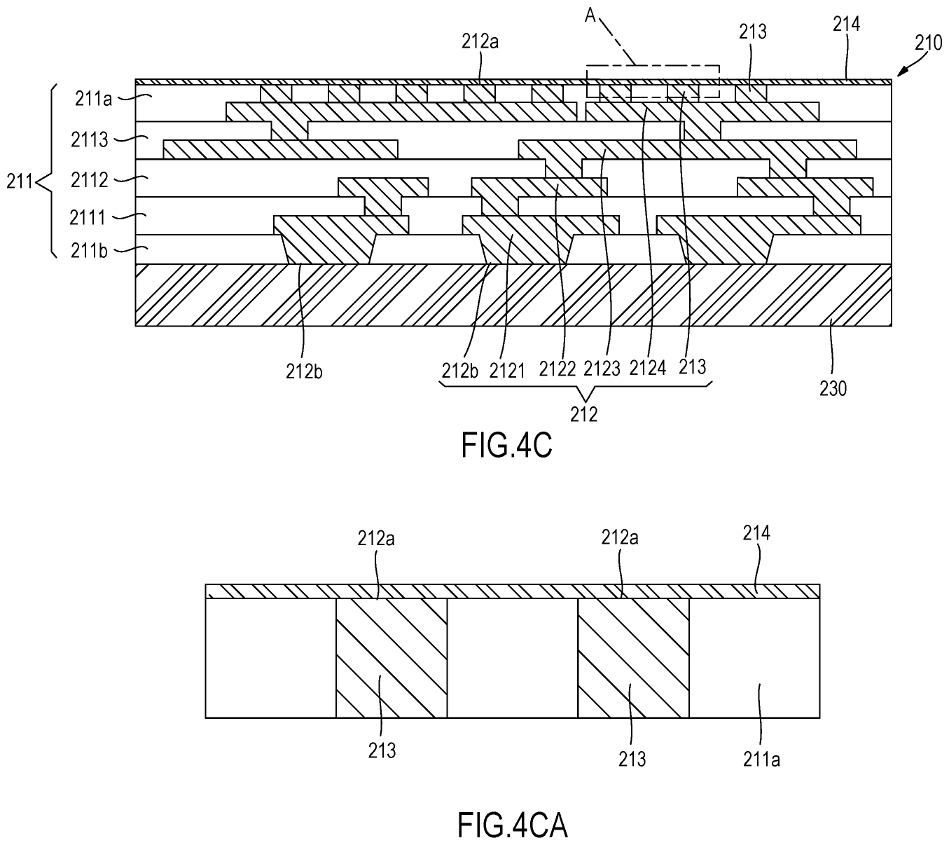

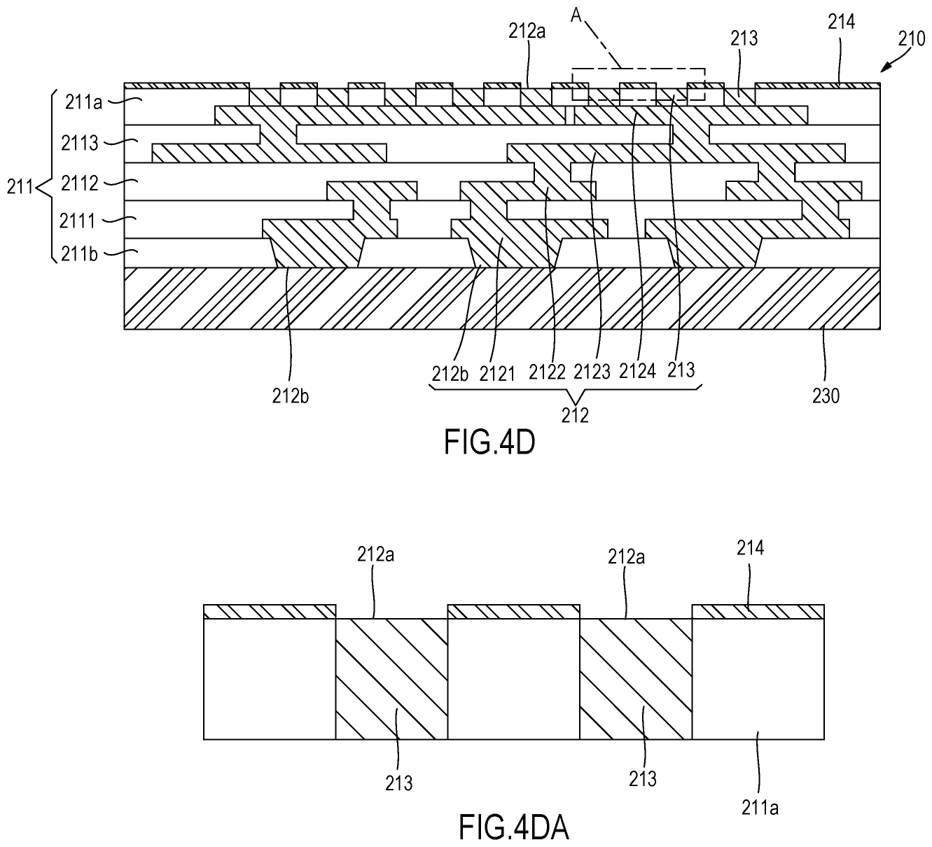

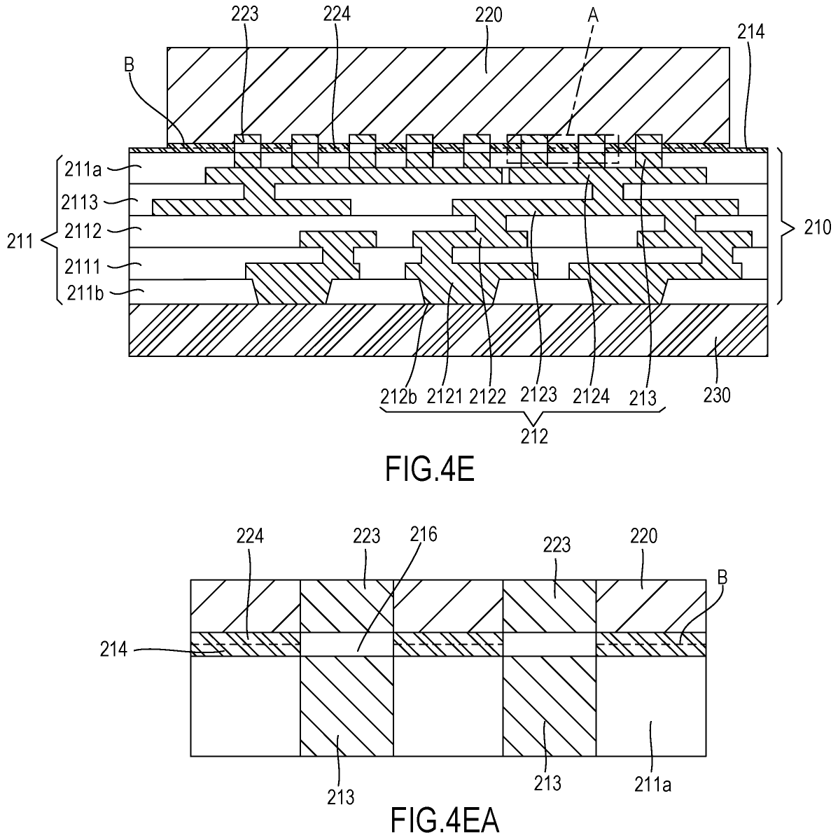

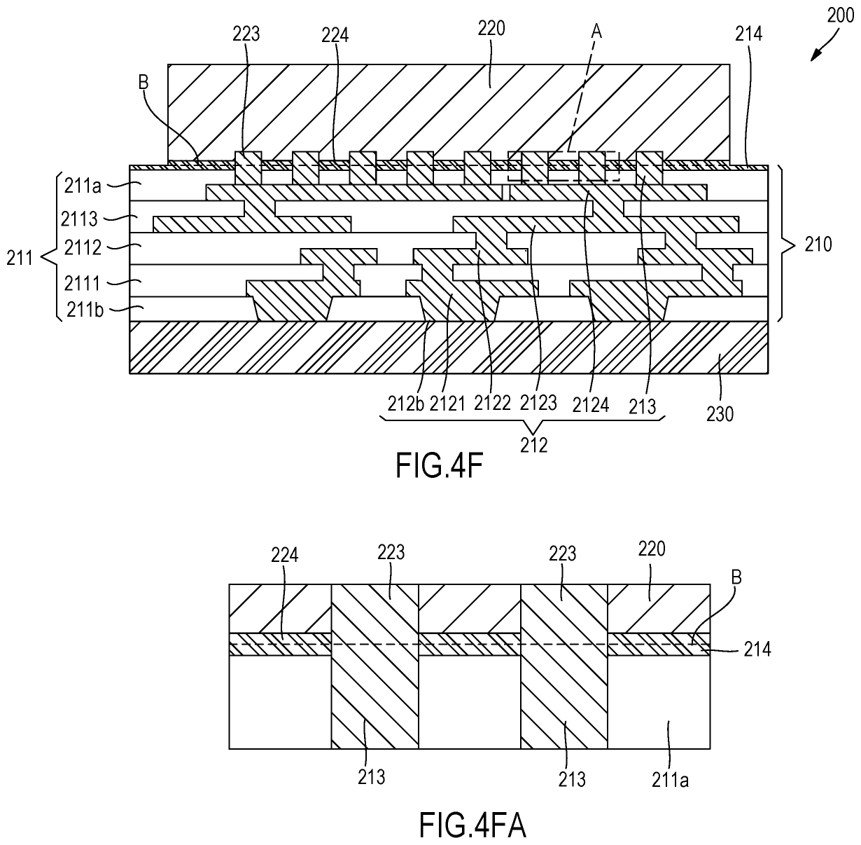

FIGS. 4A to 4F show cross-sectional views of an example method for manufacturing an example electronic device, such as electronic device 200 in FIG. 3. FIG. 4A shows electronic device 200 at an early stage of manufacture. In the example shown in FIG. 4A, conductive structure 212 and dielectric structure 211 of redistribution structure 210 can be provided on substrate 230.

In some examples, substrate 230 can comprise or be referred to as a wafer, a reconstituted wafer, or a removable carrier. For example, substrate 230 can be a wafer comprising a plurality of semiconductor die. Redistribution structure 210 can be formed over the semiconductor die to manufacture electronic devices comprising, for example, WLPs (Wafer Level Packages) or WLCSPs (Wafer Level Chip Size Packages). In some examples, substrate 230 can be a reconstituted wafer comprising a plurality of known good semiconductor die aggregated and reconstituted (e.g., encapsulated) to form substrate 230. Redistribution structure 210 can be formed over the semiconductor die and the encapsulate to manufacture electronic devices comprising, for example, WLFO (Wafer Level Fan Out) devices. In some examples, substrate 230 can comprise a removable (or temporary) carrier formed of, for example, silicon, glass, ceramic, or metal. Redistribution structure 210 can be formed on the removable carrier, and the removable carrier can be subsequently removed/separated from redistribution structure 210 to expose outward terminals 212b of conductive structure 212. In some examples, the thickness of substrate 230 can range from approximately 300 μm to approximately 2000 μm, and the width of substrate 230 can range from approximately 100 mm to approximately 300 mm. As used herein with units of distance, the term about can mean +/−5%, +/−10%, +/−15%, +/−20%, or+/−25%. Substrate 230 can support dielectric structure 211, conductive structure 212, and electronic component(s) 220 during, until, or after completion of the manufacturing process.

In some examples, outer dielectric 211b of dielectric structure 211 can be provided over substrate 230. Outer dielectric 211b can be provided to cover substrate 230 and openings corresponding to the desired location of outward terminals 212b of conductive structure 212 can be provided in outer dielectric 211b. For example, after a patterned mask (e.g., a photoresist) is provided on the upper side of dielectric structure 211, openings in outer dielectric 211b can be formed by removing exposed portions of outer dielectric 211b through, for example, etching. In some examples, outer dielectric 211b can comprise one or more layers of organic, electrically insulating material such as polyimide (PI), benzocyclobutene (BCB), polybenzoxazole (PBO), resin, or an Ajinomoto buildup film (ABF). In some examples, outer dielectric 211b can comprise an inorganic, electrically insulating material (e.g., SiO₂, Si₃N₄, SiON, Ta₂O₅, or Al₂O₃) or other dielectric material having similar insulating and structural properties. Outer dielectric 211b can be formed by spin coating, spray coating, dip coating, rod coating, PVD, CVD, printing, lamination, or any other suitable deposition process. In some examples, the thickness of outer dielectric 211b can range from approximately 3 μm to approximately 20 μm.

In accordance with various examples, conductive pattern 2121 of conductive structure 212 can be provided over the upper side of outer dielectric 211b and in the openings in outer dielectric 211b. Conductive pattern 2121 can comprise one or more layers of Al, Ti, TiW, Cu, Sn, Ni, Au, Ag, or other suitable electrically conductive material. In some examples, conductive pattern 2121 can comprise or be referred to as a conductive layer, trace(s), pad(s), conductive via(s), RDL, wiring pattern, or circuit pattern. In some examples, conductive pattern 2121 can be provided by electroplating. For example, conductive pattern 2121 can be provided in a desired pattern by providing a metal seed layer covering the upper side of outer dielectric 211b, the openings in outer dielectric 211b, and the portions of the upper side of substrate 230 that are exposed by the openings in outer dielectric 211b. A patterned mask (e.g., a patterned photoresist) can be deposited on the upper side of the seed layer. The conductive material of conductive pattern 2121 can be deposited on the portions of the seed layer exposed from the patterned mask. After the conductive material of conductive pattern 2121 is deposited, the patterned mask and the portions of the seed layer not covered by conductive pattern 2121 can be removed. Conductive pattern 2121 can also be formed using PVD, CVD, electroless plating, or other suitable metal deposition process. In some examples, the thickness of conductive pattern 2121 can range from approximately 3 μm to approximately 20 μm. In some examples, the lower (or outward) side of conductive pattern 2121 (e.g., the side that is generally coplanar with the lower side of outer dielectric 211b) can provide outward terminals 212b of conductive structure 212. Outward terminals 212b can provide I/O terminal for redistribution structure 210. In some examples, outward terminals 212b have a pitch ranging between 10 μm and 500 μm.

In some examples, dielectric 2111 of dielectric structure 211 can be provided over the upper sides of outer dielectric 211b and conductive pattern 2121 using spin coating, spray coating, dip coating, rod coating, PVD, CVD, printing, lamination, or any other suitable deposition process. Openings exposing conductive pattern 2121 can be provided in dielectric 2111. In some examples, dielectric 2111 can comprise one or more layers of organic, electrically insulating material such as PI, BCB, PBO, resin, or ABF. In some examples, dielectric 2111 can comprise an inorganic, electrically insulating material (e.g., SiO₂, Si₃N₄, SiON, Ta₂O₅, or Al₂O₃) or other dielectric material having similar insulating and structural properties. In some examples, dielectric 2111 can have elements, features, materials, or manufacturing methods similar to those of outer dielectric 211b, as previously described. In some examples, the thickness of dielectric 2111 can range from approximately 3 μm to approximately 20 μm.

In accordance with various examples, conductive pattern 2122 of conductive structure 212 can be provided over the upper sides of dielectric 2111 and conductive pattern 2121 using PVD, CVD, electrolytic plating, electroless plating process, or other suitable metal deposition process. Conductive pattern 2122 can comprise one or more layers of Al, Ti, TiW, Cu, Sn, Ni, Au, Ag, or other suitable electrically conductive material. At least one portion of conductive pattern 2122 can be coupled to conductive pattern 2121. In some examples, conductive pattern 2122 can comprise or be referred to as a conductive layer, trace(s), pad(s), conductive via(s), RDL, wiring pattern, or circuit pattern. In some examples, conductive pattern 2122 can have elements, features, materials, or manufacturing methods similar to those of conductive pattern 2121, as previously described (e.g., a seed layer, patterned mask, and electrolytic plating can be used to form conductive pattern 2122). In some examples, the thickness of conductive pattern 2122 can range from approximately 3 μm to approximately 20 μm.

In some examples, dielectric 2112 of dielectric structure 211 can be provided over the upper sides of dielectric 2111 and conductive pattern 2122 using spin coating, spray coating, dip coating, rod coating, PVD, CVD, printing, lamination, or any other suitable deposition process. Openings exposing conductive pattern 2122 can be provided in dielectric 2112. In some examples, dielectric 2112 can comprise one or more layers of organic, electrically insulating material such as PI, BCB, PBO, resin, or ABF. In some examples, dielectric 2112 can comprise an inorganic, electrically insulating material (e.g., SiO₂, Si₃N₄, SiON, Ta₂O₅, or Al₂O₃) or other dielectric material having similar insulating and structural properties. In some examples, dielectric 2112 can have elements, features, materials, or manufacturing methods similar to those of outer dielectric 211b, as previously described. In some examples, the thickness of dielectric 2112 can range from approximately 3 μm to approximately 20 μm.

In accordance with various examples, conductive pattern 2123 of conductive structure 212 can be provided over the upper sides of dielectric 2112 and conductive pattern 2122 using PVD, CVD, electrolytic plating, electroless plating process, or other suitable metal deposition process. Conductive pattern 2123 can comprise one or more layers of AI, Ti, TiW, Cu, Sn, Ni, Au, Ag, or other suitable electrically conductive material. At least one portion of conductive pattern 2123 can be coupled to conductive pattern 2122. In some examples, conductive pattern 2123 can comprise or be referred to as a conductive layer, trace(s), pad(s), conductive via(s), RDL, wiring pattern, or circuit pattern. In some examples, conductive pattern 2123 can have elements, features, materials, or manufacturing methods similar to those of conductive pattern 2121, as previously described. In some examples, the thickness of conductive pattern 2123 can range from approximately 3 μm to approximately 20 μm.

In some examples, dielectric 2113 of dielectric structure 211 can be provided over the upper sides of dielectric 2112 and conductive pattern 2123 using spin coating, spray coating, dip coating, rod coating, PVD, CVD, printing, lamination, or any other suitable deposition process. Openings exposing conductive pattern 2123 can be provided in dielectric 2113. In some examples, dielectric 2113 can comprise one or more layers of organic, electrically insulating material such as PI, BCB, PBO, resin, or ABF. In some examples, dielectric 2113 can comprise an inorganic, electrically insulating material (e.g., SiO₂, Si₃N₄, SiON, Ta₂O₅, or Al₂O₃) or other dielectric material having similar insulating and structural properties. In some examples, dielectric 2113 can have elements, features, materials, or manufacturing methods similar to those of outer dielectric 211b, as previously described. In some examples, the thickness of dielectric 2113 can range from approximately 3 μm to approximately 20 μm.

In accordance with various examples, conductive pattern 2124 of conductive structure 212 can be provided over the upper sides of dielectric 2113 and conductive pattern 2123 using PVD, CVD, electrolytic plating, electroless plating process, or other suitable metal deposition process. Conductive pattern 2124 can comprise one or more layers of Al, Ti, TiW, Cu, Sn, Ni, Au, Ag, or other suitable electrically conductive material. At least one portion of conductive pattern 2124 can be coupled to conductive pattern 2123. In some examples, conductive pattern 2124 can comprise or be referred to as a conductive layer, trace(s), pad(s), conductive via(s), RDL, wiring pattern, or circuit pattern. In some examples, conductive pattern 2123 can have elements, features, materials, or manufacturing methods similar to those of conductive pattern 2121, as previously described. In some examples, the thickness of conductive pattern 2124 can range from approximately 3 μm to approximately 20 μm.

In some examples, inner dielectric 211a of dielectric structure 211 can be provided over the upper sides of dielectric 2113 and conductive pattern 2124 using spin coating, spray coating, dip coating, rod coating, PVD, CVD, printing, lamination, or any other suitable deposition process. Openings exposing conductive pattern 2124 can be provided in inner dielectric 211a. In some examples, inner dielectric 211a can comprise one or more layers of organic, electrically insulating material such as PI, BCB, PBO, resin, or ABF. In some examples, inner dielectric 211a can comprise an inorganic, electrically insulating material (e.g., SiO₂, Si₃N₄, SiON, Ta₂O₅, or Al₂O₃) or other dielectric material having similar insulating and structural properties. In some examples, inner dielectric 211a can have elements, features, materials, or manufacturing methods similar to those of outer dielectric 211b, as previously described. In some examples, the thickness of inner dielectric 211a can range from approximately 3 μm to approximately 20 μm.

FIG. 4B shows electronic device 200 at a later stage of manufacture. In the example shown in FIG. 4B, substrate interconnects 213 of conductive structure 212 can be provided in the openings of inner dielectric 211a using PVD, CVD, electrolytic plating, electroless plating process, or other suitable metal deposition process. In some examples, substate interconnects 213 comprise copper. Substrate interconnects 213 can also comprise one or more layers of Al, Ti, TiW, Sn, Ni, Au, Ag, or other suitable electrically conductive material. In some examples, during formation of substrate interconnects 213, the conductive material of substrate interconnects 213 can be provided on the upper side of inner dielectric 211a and within the openings in inner dielectric 211a. The conductive material of substrate interconnects 213 located on the upper side of inner dielectric 211a can be removed through a CMP process, leaving substrate interconnects 213 filling the openings in inner dielectric 211a. As the result of the CMP process, the upper side of inner dielectric 211a and the upper side of substrate interconnects 213 can be coplanar.

In accordance with various examples, substrate interconnects 213 can be in contact with or coupled to conductive pattern 2124. In some examples, substrate interconnects 213 can have elements, features, materials, or manufacturing methods similar to those of interconnects 113 of electronic component 110, as described above with reference to FIGS. 2A to 2L. The upper side of substrate interconnects 213 can be inward terminals 212a of conductive structure 212. Inward terminals 212a of conductive structure 212 can provide I/O terminals for redistribution structure 210. In some examples, the thickness of substrate interconnects 213 can range from approximately 3 μm to approximately 20 μm. In some examples, substrate interconnects 213 can have a pitch of approximately 1 μm to approximately 20 μm.

While the present disclosure shows conductive structure 212 having conductive patterns 2122, 2123, 2124 between conductive pattern 2121 and substrate interconnects 213, and dielectric structure 211 having dielectrics 2111, 2112, 2113 between outer dielectric 211b and inner dielectric 211a, it is contemplated and understood that conductive structure 212 and dielectric structure 211 of redistribution structure 210 can comprise any number of interleaved conductive patterns and dielectric layers. For example, conductive structure 212 could include fewer or additional conductive pattern between conductive pattern 2121 and substrate interconnects 213, and dielectric structure 211 could include fewer or additional dielectric layers between outer dielectric 211b and inner dielectric 211a.

In accordance with various examples, redistribution structure 210 can be an RDL substrate. RDL substrates can comprise one or more conductive layers and one or more dielectric layers and (a) can be formed layer by layer over an electronic device to where the RDL substrate is to be coupled, or (b) can be formed layer by layer over a carrier and can be entirely removed or at least partially removed after the electronic device and the RDL substrate are coupled together. RDL substrates can be manufactured layer by layer as a wafer-level substrate on a round wafer in a wafer-level process, and/or as a panel-level substrate on a rectangular or square panel carrier in a panel-level process. RDL substrates can be formed in an additive buildup process and can include one or more dielectric layers alternatingly stacked with one or more conductive layers and define respective conductive redistribution patterns or traces configured to collectively (a) fan-out electrical traces outside the footprint of the electronic device, and/or (b) fan-in electrical traces within the footprint of the electronic device. The conductive patterns can be formed using a plating process such as, for example, an electroplating process or an electroless plating process. The conductive patterns can comprise a conductive material such as, for example, copper or other plateable metal. The locations of the conductive patterns can be made using a photo-patterning process such as, for example, a photolithography process and a photoresist material to form a photolithographic mask.

In some examples, the dielectric layers of the RDL substrate can be patterned with a photo-patterning process and can include a photolithographic mask through where light is exposed to photo-pattern desired features such as vias in the dielectric layers. The dielectric layers can be made from photo-definable organic dielectric materials such as, for example, PI, BCB, or PBO. Such dielectric materials can be spun-on or otherwise coated in liquid form, rather than attached as a pre-formed film. To permit proper formation of desired photo-defined features, such photo-definable dielectric materials can omit structural reinforcers or can be filler-free, without strands, weaves, or other particles, and could interfere with the light from the photo-patterning process. In some examples, such filler-free characteristics of filler-free dielectric materials can permit a reduction of the thickness of the resulting dielectric layer. Although the photo-definable dielectric materials described above can be organic materials, in some examples the dielectric materials of the RDL substrates can comprise one or more inorganic dielectric layers. Some examples of inorganic dielectric layer(s) can comprise silicon nitride (Si3N4), silicon oxide (SiO2), and/or silicon oxynitride (SiON). The inorganic dielectric layer(s) can be formed by growing the inorganic dielectric layers using an oxidation or nitridization process instead using photo-defined organic dielectric materials. Such inorganic dielectric layers can be filler-free, without strands, weaves, or other dissimilar inorganic particles. In some examples, the RDL substrates can omit a permanent core structure or carrier such as, for example, a dielectric material comprising bismaleimide triazine (BT) or FR4 and these types of RDL substrates can comprise or be referred to as a coreless substrate. Substrates as disclosed herein can comprise RDL substrates.

FIGS. 4C and 4CA show electronic device 200 at a later stage of manufacture. FIG. 4CA is an enlarged view of electronic device 200 at region A in FIG. 4C. In the examples shown in FIGS. 4C and 4CA, substrate capping layer 214 can be provided to cover the upper side of dielectric structure 211 and the upper side of conductive structure 212 using PVD, CVD, MOCVD, ALD, LPCVD, PECVD, spin coating, spray coating, dip coating, or rod coating. Substrate capping layer 214 can be on or in contact with the upper side of inner dielectric 211a and the upper side of substrate interconnects 213. In some examples, substrate capping layer 214 can be formed with structures and techniques similar to or the same as those of capping layer 114, as described above in FIGS. 2A-2L. For example, substrate capping layer 214 can extend into a recess or trench surrounding an upper portion of substrate interconnect 213. The portion of substrate capping layer 214 in the recess can be located between an interior sidewall of inner dielectric 211a and the upper portion of substrate interconnect 213 and can extend to the top side of a seed layer located between inner dielectric 211a and substrate interconnect 213.

In some examples, substrate capping layer 214 can be made of an inorganic material, such as an oxide or a nitride. For example, substrate capping layer 214 can be made of SiO2, Si3N4, SiON, or Al2O3. In some examples, inner dielectric 211a can comprise an organic material (e.g., PI), and the inorganic material of substrate capping layer 214 can be formed on a surface of the organic material of inner dielectric 211a. Using an inorganic material for the substate capping layer 214 and an organic material for one or more of the dielectrics of dielectric structure 211 tends to reduce manufacturing costs and/or allows inorganic capping layers to be applied to RDL substrates that are manufactured in locations or by manufactures that generally do not provide substrates having inorganic dielectric layers. Additionally, the thickness of the substate capping layer 214 tends to be more easily controlled, allowing for greater accuracy in dishing depth and reduced occurrence of bonding failures. In some examples, the thickness of substrate capping layer 214 can range from approximately 1 nm to approximately 100 nm. The thinness of substrate capping layer 214 can also reduce or prevent the generation of wrinkles during deposition.

FIGS. 4D and 4DA show electronic device 200 at a later stage of manufacture. FIG. 4DA is an enlarged view of electronic device 200 at region A of FIG. 4D. In the example of FIGS. 4D and 4DA, portions of substrate capping layer 214 can be removed and the upper side of substrate interconnects 213 can be exposed. For example, a mask can be provided on the upper side of substrate capping layer 214. The mask can be patterned to expose portions of substrate capping layer 214 located on substrate interconnects 213. The exposed portions of substrate capping layer 214 can be removed through etching. The mask, which can be a photoresist in some examples, can be removed after patterning substrate capping layer 214.

Redistribution structure 210 can comprise dielectric structure 211, conductive structure 212, substrate interconnects 213, and substrate capping layer 214. Substrate capping layer 214 can protrude upward from substrate interconnects 213. Stated differently, substrate interconnects 213 can be recessed or dished with respect to substrate capping layer 214. The thickness of substrate capping layer 214 can be selected to compensate for the thermal expansion of substrate interconnects 213 or for the difference in the thermal expansion coefficient of dielectric structure 211 and the thermal expansion coefficient of substrate interconnects 213.

FIGS. 4E and 4EA show electronic device 200 at a later stage of manufacture. FIG. 4EA is an enlarged view of electronic device 200 in region A of FIG. 4E. In the examples shown in FIGS. 4E and 4EA, electronic component 220 can be provided on the upper side of redistribution structure 210.

Electronic component 220 can comprise component interconnects 223 and component capping layer 224. Component interconnects 223 can be coupled to the bond pads of electronic component 220. In some examples, component interconnects 223 can be bond pads of electronic component 220. In some examples, component interconnects 223 can comprise copper. In some examples, component interconnects 223 can be formed by plating. In some examples, the lower side of component interconnects 223 can be coplanar with the lower (e.g., the front or active) side of electronic component 220. In some examples, component interconnects 223 of electronic component 220 can have elements, features, materials, or manufacturing methods similar to or the same as those of interconnects 113 of electronic component 110.

In accordance with various examples, component capping layer 224 can be located on or in contact with the lower side of electronic component 220. Component interconnects 223 are exposed from component capping layer 224. The lower side of component capping layer 224 can protrude relative to the lower side of component interconnects 223. In this regard, component interconnect 223 can be recessed or dished with respect to component capping layer 224. In some examples, component capping layer 224 can have elements, features, materials, or manufacturing methods similar to or the same as those of substrate capping layer 214 of redistribution structure 210. In some examples, component capping layer 224 can have corresponding elements, features, materials, or manufacturing methods similar to or the same as those of capping layer 114 of electronic component 110. In some examples, electronic component 220 can comprise a dielectric structure similar to or the same as dielectric structure 111 of electronic component 110, and component interconnect 223 can be coplanar with the dielectric structure. In some examples, electronic component 220 can comprise a seed layer and a recess similar to or the same as seed layer 112 and recess 115, respectively, of electronic component 110, and component capping layer 224 can extend into the recess and can contact the seed layer.

In some examples, pick-and-place equipment can pick up electronic component 220, and place electronic component 220 on redistribution structure 210 with component capping layer 224 of electronic component 220 placed on the upper side of substrate capping layer 214. After component capping layer 224 is located on substrate capping layer 214, component interconnects 223 of electronic component 220 and substrate interconnects 213 of redistribution structure 210 can be spaced apart from each other to define void 216. Through a hybrid bonding process, component capping layer 224 of electronic component 220 can be bonded to substrate capping layer 214 of redistribution structure 210. For example, component capping layer 224 and substrate capping layer 214 can be subjected to surface activation, before being coupled together, to enable low-temperature coupling. The surface activation of component capping layer 224 and substrate capping layer 214 can be similar to or the same as the surface activation of capping layer 114 of electronic component 110 and capping layer 124 of electronic component 120. In some examples, component capping layer 224 can be coupled to substrate capping layer 214 at a temperature ranging from approximately 25° C. to approximately 400° C.

FIGS. 4F and 4FA show electronic device 200 at a later stage of manufacture. FIG. 4FA is an enlarged view of portion A of FIG. 4F. In the examples shown in FIGS. 4F and 4FA, component interconnects 223 of electronic component 220 can be coupled to substrate interconnects 213 of redistribution structure 210.

Component interconnects 223 can be coupled to substrate interconnects 213 at a greater temperature than the temperature employed during the coupling of component capping layer 224 to substrate capping layer 214. For example, component interconnects 223 can be coupled to substrate interconnects 213 of redistribution structure 210 through a hybrid bonding process. In some examples, component interconnects 223 can be coupled to substrate interconnects 213 at a temperature ranging from approximately 150° C. to approximately 400° C. During bonding, temperature increase can cause thermal expansion of component interconnects 223 or substrate interconnects 213. In accordance with various examples, coefficients of thermal expansion of component interconnects 223 and substrate interconnects 213 can be greater than the coefficients of thermal expansion of component capping layer 224 and substrate capping layer 214. The void created by thicknesses of component capping layer 224 and substrate capping layer 214 can be configured to allow for the thermal expansion of component interconnects 223 or substrate interconnects 213 and cause contact and coupling between component interconnects 223 and substrate interconnects 213 without separating (or breaking the bond between) component capping layer 224 and substate capping layer 214.

Electronic device 200 and redistribution structure 210 can be coupled to each other by low-temperature hybrid bonding. When being coupled together, component interconnect 223 and substrate interconnect 213 can expand to be in contact with and coupled to each other. The void created by thicknesses of component capping layer 224 and substrate capping layer 214 can prevent or reduce occurrences of substrate capping layer 214 and component capping layer 224 from being separated from each other due to thermal expansion of substate interconnect 213 or component interconnects 223. In some examples, the direct bond between substrate interconnect 213 and component interconnect 223 can comprise or be referred as a fusion bond or a solderless bond. In some examples, the direct bond can comprise grain growth of the material of substrate interconnects 213 or component interconnect 223 into each other. In some examples, a direct bond can be established by pressure from substrate interconnect 213 and component interconnect 223 expanding towards each other due to heat while secured by the bond between substrate capping layer 214 and component capping layer 224.

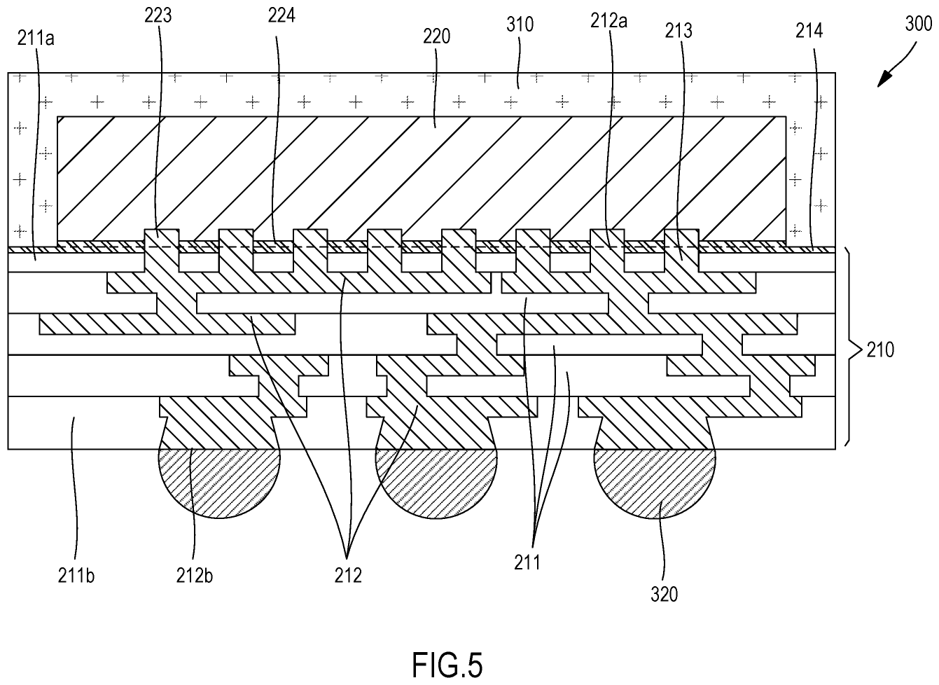

FIG. 5 shows a cross-sectional view of an example electronic device 300. In the example of FIG. 3, electronic device 300 can comprise redistribution structure 210 and electronic component 220. In some examples, electronic device 300 can comprise encapsulant 310 and external interconnects 320.

Redistribution structure 210 can comprise dielectric structure 211, conductive structure 212, and substrate capping layer 214. Dielectric structure 211 can comprise inner dielectric 211a and outer dielectric 211b. Conductive structure 212 can comprise substrate interconnects 213. Electronic component 220 can comprise component interconnects 223 and component capping layer 224.

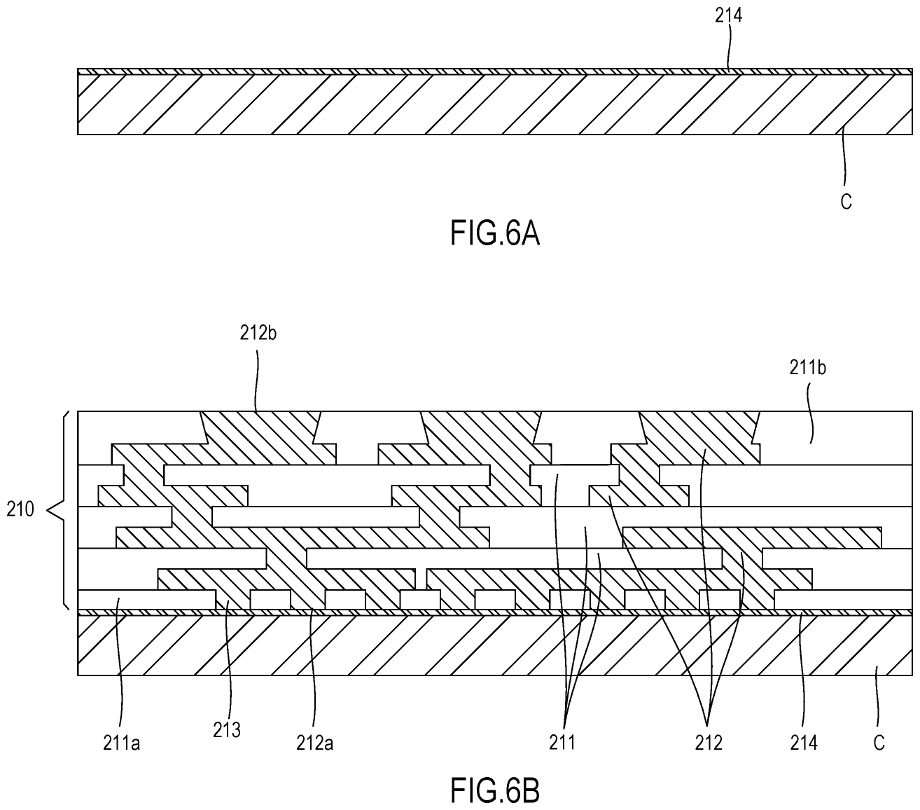

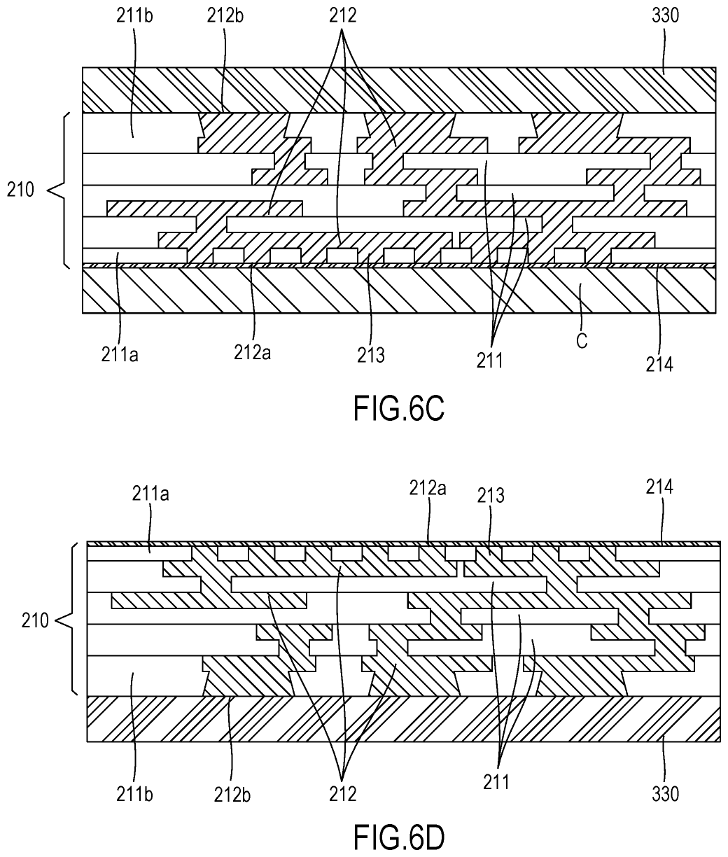

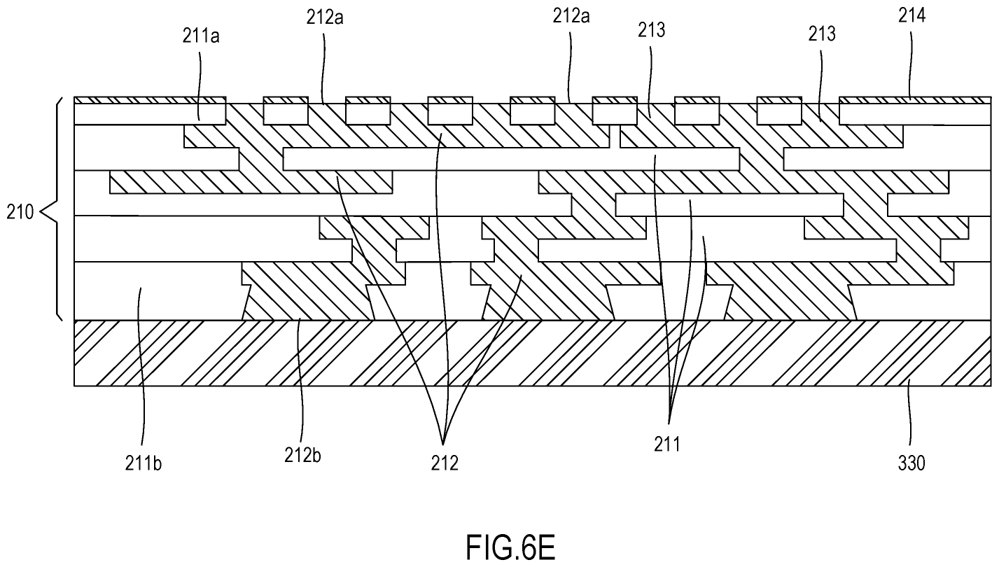

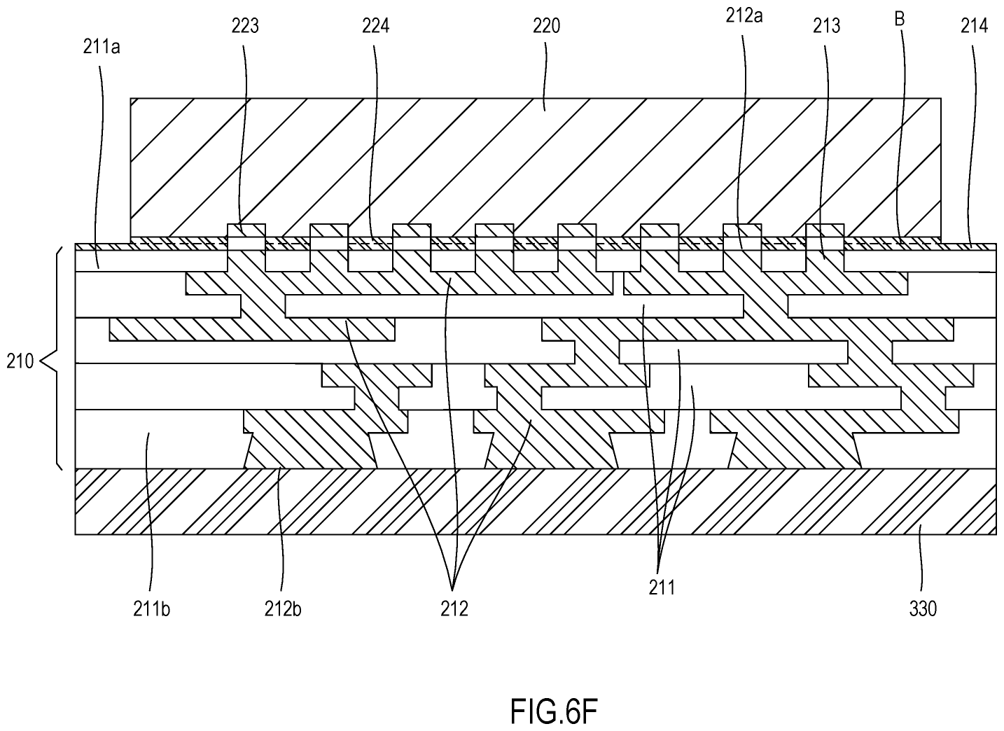

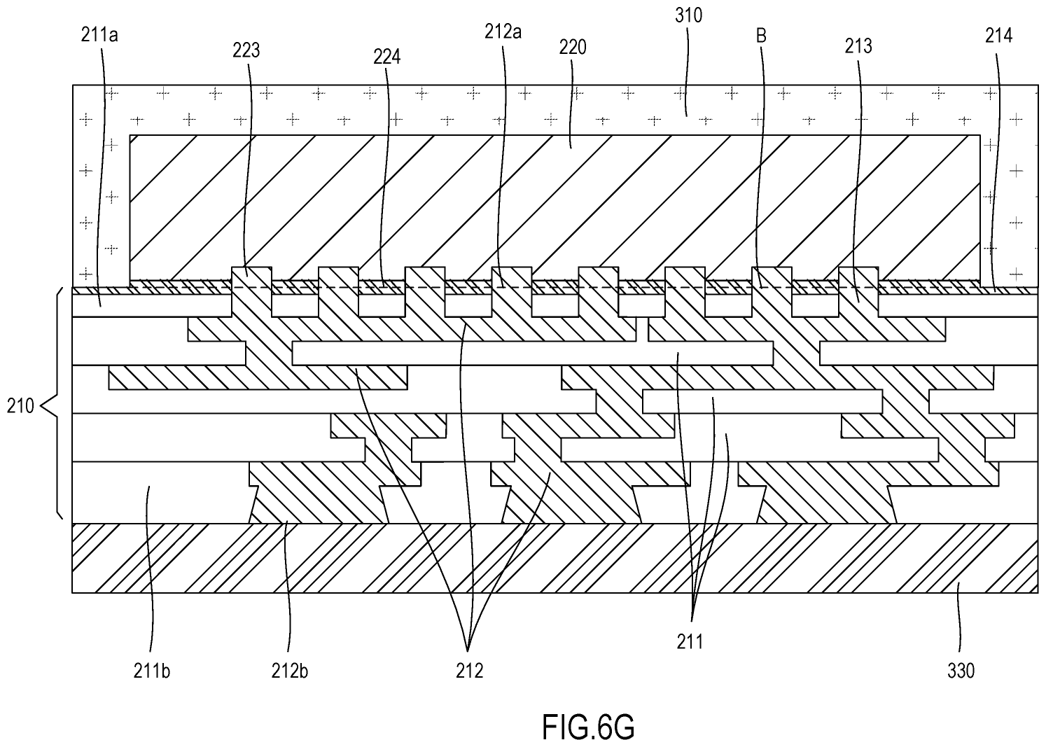

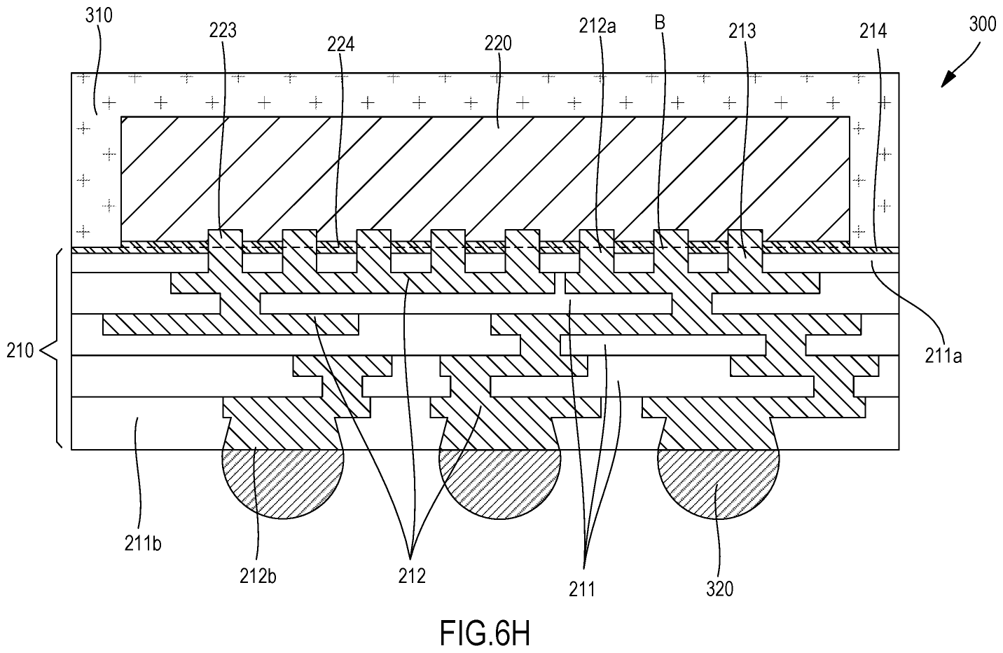

FIGS. 6A to 6H show cross-sectional views of an example method for manufacturing an example electronic device, such as electronic device 300 in FIG. 5. FIG. 6A shows electronic device 300 at an early stage of manufacture. In the example shown in FIG. 6A, substrate capping layer 214 can be provided on the upper side of carrier substrate C. Substrate capping layer 214 can have elements, features, materials, or manufacturing methods similar to or the same as those of substrate capping layer 214 shown in FIG. 4C.

In some examples, carrier substrate C can comprise silicon or other semiconductor material. In some examples, carrier substrate C can comprise a glass or metal plate. In some examples, carrier substrate C can comprise a core or coreless substrate including one or more layers of any of a variety of dielectric materials, for example inorganic dielectric material (e.g., Si₃N₄, SiO₂, SiON, SiN, oxides, nitrides, etc.) and/or organic dielectric material (e.g., a polymer, PI, BCB, PBO, BT, a molding material, a phenolic resin, an epoxy, etc.). In some examples, carrier substrate C can comprise a temporary bond layer, such that the temporary bond layer is located between substrate capping layer 214 and carrier substrate C. As described in further detail below, the temporary bond layer can allow carrier substrate C to be separated from substrate capping layer 214.

FIG. 6B shows electronic device 300 at a later stage of manufacture. In the example shown in FIG. 6B, redistribution structure 210, including conductive structure 212 and dielectric structure 211, can be provided on substrate capping layer 214 and substrate carrier C. As shown in FIG. 6B, substrate interconnects 213 and inner dielectric 211a can be provided on the upper side of substrate capping layer 214. For example, substrate interconnects 213 and inner dielectric 211a can be proximate substrate carrier C, and outward terminals 212b and outer dielectric 211b can be distal substrate carrier C. Substrate interconnects 213 can be provided in a desired pattern (e.g., rows or columns) on substrate capping layer 214. In some examples, the thickness of substrate interconnects 213 can range from approximately 3 μm to approximately 20 μm. Dielectric structure 211 and conductive structure 212 can have elements, features, materials, or manufacturing methods similar to or the same as those of dielectric structure 211 and conductive structure 212, respectively, shown in FIG. 4A.

In some examples, substrate interconnects 213 and inner dielectric 211a can be formed first on substrate capping layer 214 and substrate carrier C, and subsequent dielectrics of dielectric structure 211 and conductive patterns of conductive structure 212 can be formed on or after substrate interconnects 213 and inner dielectric 211a. Providing substrate capping layer 214, substrate interconnects 213, and inner dielectric 211a on substrate carrier C can increase the flatness (or planarity) of substrate capping layer 214, substrate interconnects 213, or inner dielectric 211a. For example, providing substrate capping layer 214, substrate interconnects 213, and inner dielectric 211a on substrate carrier C can decrease the chances for grooves or unevenness on the side of substrate capping layer 214 and the side of substrate interconnects 213 that are oriented toward substrate carrier C, which can improve bonding performance and reduce a likelihood of bonding failures.

FIG. 6C shows electronic device 300 at a later stage of manufacture. In the example shown in FIG. 6C, removable carrier 330 can be provided on outer dielectric 211b of dielectric structure 211 and outward terminals 212b of conductive structure 212. Removable carrier 330 can be formed of, for example, silicon, glass, ceramic, metal, or any other suitable material. Removable carrier 330 can support dielectric structure 211, conductive structure 212, substrate capping layer 214, and electronic component(s) 220 (FIG. 6F) during subsequent manufacturing processes. In some examples, removable carrier 330 can comprise a temporary bond layer, such that the temporary bond layer is located between redistribution structure 210 and removable carrier 330. As described in further detail below, the temporary bond layer can allow removable carrier 330 to be separated from outer dielectric 211b and outward terminals 212b of redistribution structure 210.

FIG. 6D shows electronic device 300 at a later stage of manufacture. In FIG. 6D, electronic device 200 has been rotated 180° such that removable carrier 330 is located at the bottom of the FIG. 6D. In the example of FIG. 6D, carrier substrate C can be separated from substrate capping layer 214.

In some examples, carrier substrate C can be separated from substrate capping layer 214 and redistribution structure 210 (in-whole or in-part) by, for example, grinding, peeling, or etching. When carrier substrate C is removed, substrate capping layer 214 can remain over inner dielectric 211a and substrate interconnects 213. In some examples, carrier substrate C can comprise a temporary bond layer, and substrate capping layer 214 can be provided on the temporary bond layer. The temporary bond layer can comprise, for example, a temporary adhesive film, a temporary adhesive tape, or a temporary adhesive coating. In some examples, the temporary bond layer can be a heat release tape (film) or an optical release tape (film), in which the adhesive strength can be weakened or removed by heat or light, respectively. In some examples, the temporary bond layer can have its adhesive force weakened or removed by external physical or chemical force. The temporary bond layer can allow carrier substrate C to be separated from substrate capping layer 214 before patterning substrate capping layer 214, as further described below.

FIG. 6E shows electronic device 300 at a later stage of manufacture. In the example shown in FIG. 6E, substrate capping layer 214 can be patterned to expose the upper side of substrate interconnects 213. The patterning of substrate capping layer 214 can be similar to or the same as substrate capping layer 214 shown in FIG. 4D. Redistribution structure 210 can comprise dielectric structure 211, conductive structure 212 including substrate interconnects 213 and outward terminals 212b, and substrate capping layer 214.

Substrate capping layer 214 can protrude above substrate interconnects 213, such that the upper side of substrate interconnects 213 is recessed or dished relative to substrate capping layer 214. By providing substrate interconnects 213 and inner dielectric 211a on substrate capping layer 214, the upper side of substrate interconnects 213 and the upper side of dielectric structure 211 can formed coplanar with one another, which can eliminate the need for a surface planarizing process (e.g., the CMP process described above with respect to FIG. 4B can be eliminated). Eliminating the surface planarizing process can simplify the manufacturing process and/or decrease manufacturing costs.

FIGS. 6F and 6G show electronic device 300 at later stages of manufacture. In the example shown in FIGS. 6F and 6G, electronic component 220 and redistribution structure 210 can be coupled to each other. Coupling of component capping layer 224 of electronic component 220 and substrate capping layer 214 of redistribution structure 210 can be similar to or the same as coupling component capping layer 224 of electronic component 220 and substrate capping layer 214 of redistribution structure 210, shown in FIG. 4E. Coupling of component interconnects 223 of electronic component 220 and substrate interconnects 213 of redistribution structure 210 can be similar to or the same as component interconnects 223 of electronic component 220 and substrate interconnects 213 of redistribution structure 210 shown in FIG. 4F.

In the example shown in FIG. 6G, encapsulant 310 can be provided over substrate capping layer 214 and electronic component 220. Encapsulant 310 can comprise or be referred to as a package body, mold body, or molding. For example, encapsulant 310 can comprise an epoxy mold compound, a resin, a filler-reinforced polymer, a B-stage pressed film or gel. Encapsulant 310 can be formed by compression molding, transfer molding, liquid body molding, vacuum lamination, paste printing, or film assist molding. While FIG. 6G shows encapsulant 310 located on the backside of electronic component 220, it is contemplated and understood that in various examples, encapsulant 310 can be coplanar with the backside of electronic component 220.

FIG. 6H shows electronic device 300 at a later stage of manufacture. In the example shown in FIG. 6H, removable carrier 330 can be separated from outer dielectric 211b and outward terminals 212b. In some examples, the adhesive strength of a temporary bond layer of removable carrier 330 can be removed or reduced by providing heat, light, a chemical solution, or physical external force to separate removable carrier 330 from outer dielectric 211b and outward terminals 212b. Removal of removable carrier 330 exposes outer dielectric 211b and outward terminals 212b.

In accordance with various examples, external interconnects 320 can be provided on outward terminals 212b. In some examples, an under-bump metallization (UBM) can be provided between external interconnects 320 and outward terminals 212b. External interconnects 320 can be coupled to outward terminals 212b. External interconnects 320 can be coupled to electronic component 220 through conductive structure 212 of redistribution structure 210. In some examples, external interconnects 320 can comprise or be referred to as conductive balls or bumps (e.g., solder balls or solder bumps), conductive pillars or posts (e.g., copper pillars or copper posts), or conductive posts with solder caps. In some examples, external interconnects 320 can comprise tin (NS), silver (Ag), lead (Pb), copper (Cu), Sn—Pb, Sn37-Pb, Sn95-Pb, Sn—Pb—Ag, Sn—Cu, Sn—Ag, Sn—Au, Sn—Bi, or Sn—Ag—Cu. For example, external interconnects 320 can be formed through a reflow process after forming a conductive material including solder on outward terminals 212b of conductive structure 212 through a ball drop method. In some examples, the height of external interconnects 320 can range from approximately 0.25 mm to approximately 1.5 mm. In some examples, external interconnects 320 can be referred to as external input/output terminals of electronic device 300. In some examples, a singulation (e.g., sawing or cutting) operation can be performed through encapsulant 310 and redistribution structure 210, thereby providing individual electronic devices 300.

Devices and methods described herein tend to improve bond performance by controlling a height of a capping layer adjacent an interconnect. The interconnect can be recessed from the capping layer by a dishing height or dishing depth. The dishing height is controlled by controlling the thickness of the capping layer. The controlled height of the capping layer tends to allow sufficient room to accommodate thermal expansion of the interconnect during bonding. Interconnects can bond directly without separating bonded capping layers or other bonded dielectrics. The interconnects have a precise amount of space to expand, through thermal expansion or pressure, into contact and bond with one another without forcing adjacent capping layers to separate.

The present disclosure includes reference to certain examples; however, it will be understood by those skilled in the art that various changes may be made, and equivalents may be substituted without departing from the scope of the disclosure. In addition, modifications may be made to the disclosed examples without departing from the scope of the present disclosure. Therefore, it is intended that the present disclosure not be limited to the examples disclosed, but that the disclosure will include all examples falling within the scope of the appended claims.

What is claimed is:

1. An electronic device comprising:
a first electronic component;
a dielectric structure that defines a via extending from an upper side of the dielectric structure to an upper side of the first electronic component;
a first interconnect disposed in the via, wherein an upper side of the first interconnect is substantially coplanar with the upper side of the dielectric structure;
a seed layer between the first interconnect and the dielectric structure, wherein an end of the seed layer is recessed from the upper side of the dielectric structure and the upper side of the first interconnect; and
a capping layer disposed on the dielectric structure and extending to the end of the seed layer between the first interconnect and the dielectric structure.

2. The electronic device of claim 1, wherein the capping layer comprises a height of approximately 1 nanometer from the dielectric structure.

3. The electronic device of claim 1, wherein the capping layer defines an opening that exposes the upper side of the first interconnect for bonding.

4. The electronic device of claim 3, wherein the upper side of the first interconnect is recessed from an upper side of the capping layer by a dishing height.

5. The electronic device of claim 1, wherein the capping layer comprises an L-shaped profile.

6. The electronic device of claim 1, wherein a first height of the capping layer over the end of the seed layer is greater than a second height of the capping layer over the dielectric structure.

7. A method of making an electronic device, comprising:
providing a redistribution structure comprising a substrate interconnect;
removing a portion of a first capping layer to expose a side of the substrate interconnect, wherein the side of the substrate interconnect is recessed by a dishing height from a side of the first capping layer;
providing an electronic component over the first capping layer, wherein the electronic component comprises a second capping layer and a component interconnect;
bonding the second capping layer with the first capping layer; and
applying heat to bond the substrate interconnect to the component interconnect.

8. The method of claim 7, wherein the first capping layer and the second capping layer comprise an inorganic dielectric material.

9. The method of claim 7, wherein the redistribution structure comprises an inner dielectric, and wherein the first capping layer comprises a thickness of approximately 1 nanometer, as measured from an upper side of the inner dielectric.

10. The method of claim 7, wherein the redistribution structure comprises an inner dielectric, and wherein the redistribution structure comprises a seed layer between the inner dielectric and the substrate interconnect.

11. The method of claim 10, wherein the first capping layer extends to an end of the seed layer between the substrate interconnect and the inner dielectric.

12. The method of claim 7, wherein the first capping layer comprises an L-shaped profile.

13. The method of claim 7, wherein providing the substrate interconnect comprises:
providing a conductive material over a side of an inner dielectric of the redistribution structure and filling a via defined by the inner dielectric; and
removing the conductive material from over the side of the inner dielectric to leave the conductive material protruding above the via.

14. A method of making an electronic device, comprising:
providing a first electronic component;
providing a dielectric structure over the first electronic component, wherein a sidewall of the dielectric structure defines a via extending from an upper side of the dielectric structure to the first electronic component;
providing a seed layer over the first electronic component, the upper side of the dielectric structure, and the sidewall of the dielectric structure;
providing a first component interconnect over the seed layer, wherein the first component interconnect fills the via and covers the side of the dielectric structure;
removing a portion of the first component interconnect to leave an upper side of the first component interconnect recessed from the seed layer;
removing a portion of the seed layer to expose the upper side of the dielectric structure and leave an end of the seed layer recessed from the dielectric structure and between the first component interconnect and the dielectric structure;
providing a first capping layer over the dielectric structure, the first capping layer extending to the end of the seed layer between the first component interconnect and the dielectric structure; and
removing a portion of the first capping layer to expose the upper side of the first component interconnect, wherein the upper side of the first component interconnect is recessed from an upper side of the first capping layer by a first dishing height.

15. The method of claim 14, wherein the first dishing height is approximately 1 nanometer.

16. The method of claim 14, further comprising:
providing a redistribution structure comprising a second capping layer and a substrate interconnect located at an inner side of the redistribution structure;
bonding the second capping layer with the first capping layer; and
applying heat to bond the substrate interconnect to the first component interconnect.

17. The method of claim 16, wherein the first capping layer and the second capping layer comprise an inorganic dielectric material.

18. The method of claim 16, wherein providing the redistribution structure further comprises:
providing the substrate interconnect on a first side of the second capping layer; and
removing a portion of the second capping layer to expose an upper side of the substrate interconnect, wherein the upper side of the substrate interconnect is recessed by a dishing height from a second side of the second capping layer opposite the first side of the second capping layer.

19. The method of claim 14, further comprising:
providing a second electronic component comprising a second capping layer and a second component interconnect;
bonding the second capping layer with the first capping layer; and
applying heat to bond the second component interconnect to the first component interconnect.

20. The method of claim 16, further comprising providing an encapsulant over the second capping layer and around a sidewall of the first capping layer.
